(19) United States
(12) Patent Application Publication
(10) Pub. No.: US 2021/0335873 A1
(43) Pub. Date: Oct. 28, 2021

(54) PHOTOELECTRIC CONVERSION DEVICE, MANUFACTURING METHOD THEREOF, AND DISPLAY DEVICE

(71) Applicant: Shenzhen China Star Optoelectronics Semiconductor Display Technology Co., Ltd., Shenzhen (CN)

(72) Inventors: Yu ZHANG, Shenzhen, Guangdong (CN); Miao JIANG, Shenzhen, Guangdong (CN); Jiangbo YAO, Shenzhen, Guangdong (CN); Lixuan CHEN, Shenzhen, Guangdong (CN); Xin ZHANG, Shenzhen, Guangdong (CN)

(21) Appl. No.: 16/962,077

(22) PCT Filed: Jul. 3, 2020
(86) PCT No.: PCT/CN2020/100097

§ 371 Date: Jul. 14, 2020

(30) Foreign Application Priority Data
Apr. 28, 2020 (CN) 202010351527.4

(51) Int. Cl. H01L 27/146; H04N 5/378

(52) U.S. Cl. CPC H01L 27/14636; H04N 5/378; H01L 27/14643

(57) ABSTRACT

A photoelectric conversion device, a manufacturing method thereof, and a display device are provided. The photoelectric conversion device includes a substrate and a thin film transistor unit layer arranged on the substrate. The photoelectric conversion device includes a photosensitive surface. The thin film transistor unit layer includes an active layer, a source-drain metal layer positioned at both ends of the active layer and electrically connected to the active layer, and a photonic crystal functional layer disposed on a side of the active layer away from the photosensitive surface.

### FIELD OF INVENTION

The present application relates to the field of display technologies, and in particular to a photoelectric conversion device, a manufacturing method thereof, and a display device.

### BACKGROUND OF INVENTION

With advent of 5G era, the internet of things and smart home are coming one after another. In the 5G era, there are higher requirements for new products, such as being smarter, mobile, more integrated, modular, customized, and sustainable.

In a new era, display devices will not only serve as display carriers of image screens, more intelligent design and development are imperative. An integration of sensors provides more directions for intelligent development of display devices, such as photosensitive sensors, which realize an interaction between each wavelength band of light and panels; touch sensors for precise multi-point touch; and non-touch sensors for gesture recognition and facial recognition. Therefore, it is very necessary to study about how to increase preciseness of the sensors and have wide adaptability.

### Technical Problem

A photoelectric conversion performance of active materials is widely used in many fields, such as photodetectors and photovoltaic devices, by generating photon absorption and carrier transmission of electron-hole pairs. However, the basic band gap, which is limited by active materials, is too narrow and can only respond to light of a specific wavelength band. A light response performance is weak and the light utilization rate is low, which makes a response performance of a photoelectric conversion device lower.

### SUMMARY OF INVENTION

### Technical Solution

The purpose of the present application is to provide a photoelectric conversion device and a method of manufacturing same, and a display device, used to overcome technical problems that the photoelectric conversion device can only respond to light of a specific wavelength band, the light response performance is weak, and the light utilization rate is low, result in the response performance of the photoelectric conversion device lower.

In order to solve the above problems, the present application provides a photoelectric conversion device, including a substrate and a thin film transistor unit layer arranged on the substrate, the photoelectric conversion device including a photosensitive surface, wherein the thin film transistor unit layer includes:

an active layer;

a source-drain metal layer positioned at both ends of the active layer and electrically connected to the active layer; and

a photonic crystal functional layer disposed on a side of the active layer away from the photosensitive surface.

In the photoelectric conversion device of the present application, the photonic crystal functional layer includes an inverse opal structure.

In the photoelectric conversion device of the present application, a material of the photonic crystal functional layer is same as a material of the active layer.

In the photoelectric conversion device of the present application, a material of the photonic crystal functional layer is one of zirconia, silicon oxide, tungsten oxide, manganese oxide, titanium oxide, germanium oxide, or polycrystalline silicon.

In the photoelectric conversion device of the present application, the photonic crystal functional layer is doped with a lanthanide metal oxide or a rare earth element.

In the photoelectric conversion device of the present application, the thin film transistor unit layer further includes:

a gate layer provided on the substrate; and

a gate insulating layer disposed on the substrate and the gate insulating layer and covering the gate layer; wherein the active layer is disposed on the gate insulating layer.

In the photoelectric conversion device of the present application, the thin film transistor unit layer further includes:

a gate insulating layer disposed on the active layer;

a gate layer disposed on the gate insulating layer; and

an interlayer insulating layer disposed on the gate insulating layer and completely covering the gate layer; wherein the source-drain metal layer is electrically connected to both ends of the active layer through the interlayer insulating layer.

The present application further provides a method of manufacturing a photoelectric conversion device, including following steps:

providing a substrate; and

forming a thin film transistor unit layer on the substrate;

wherein the photoelectric conversion device includes a photosensitive surface, and forming the thin film transistor unit layer includes:

forming an active layer on the substrate;

forming a source-drain metal layer on both ends of the active layer; and

forming a photonic crystal functional layer on a side of the active layer away from the photosensitive surface.

In the method of manufacturing the photoelectric conversion device of the present application, the photonic crystal functional layer is formed by one of chemical vapor deposition process, atomic layer deposition process, sol-gel process, or two-photon laser direct writing process.

The present application further provides a display device including the photoelectric conversion device according to any one of the previous embodiments.

In the display device of the present application, the photonic crystal functional layer includes an inverse opal structure.

In the display device of the present application, a material of the photonic crystal functional layer is same as a material of the active layer.

In the display device of the present application, a material of the photonic crystal functional layer is one of zirconia, silicon oxide, tungsten oxide, manganese oxide, titanium oxide, germanium oxide, or polycrystalline silicon.

In the display device of the present application, the photonic crystal functional layer is doped with a lanthanide metal oxide or a rare earth element.

In the display device of the present application, the thin film transistor unit layer further includes:

a gate layer provided on the substrate; and

a gate insulating layer disposed on the substrate and the gate insulating layer and covering the gate layer; wherein the active layer is disposed on the gate insulating layer.

In the display device of the present application, the thin film transistor unit layer further includes:

a gate insulating layer disposed on the active layer;

a gate layer disposed on the gate insulating layer; and

an interlayer insulating layer disposed on the gate insulating layer and completely covering the gate layer; wherein the source-drain metal layer is electrically connected to both ends of the active layer through the interlayer insulating layer.

### Beneficial Effect

The beneficial effects of the present application are as follows. By applying a photonic crystal technique to the photoelectric conversion device, the photonic crystal functional layer is disposed on the side of the active layer away from the photosensitive surface, and the light incident from the photosensitive surface is reflected by the photonic crystal functional layer to the active layer to realize a secondary stimulus response of the active layer to light, enhancing the photoelectric conversion device and improving the response performance. In addition, the photonic crystal functional layer can also convert light in other bands that the active layer cannot respond to into light that the active layer can respond to, which further improves the light utilization efficiency of the photoelectric conversion device and adaptability to light in different bands.

### BRIEF DESCRIPTION OF FIGURES

In order to illustrate the technical solutions of the present disclosure or the related art in a clearer manner, the drawings desired for the present disclosure or the related art will be described hereinafter briefly. Obviously, the following drawings merely relate to some embodiments of the present disclosure, and based on these drawings, a person skilled in the art may obtain the other drawings without any creative effort.

FIG. 1 is a schematic structural diagram of a first photoelectric conversion device according to an embodiment of the present application.

FIG. 2 is a schematic structural diagram of a second photoelectric conversion device according to an embodiment of the present application.

FIG. 3 is a schematic structural diagram of a third photoelectric conversion device according to an embodiment of the present application.

FIG. 4 is a flowchart of a method of manufacturing a photoelectric conversion device according to an embodiment of the present application.

FIG. 5 is a schematic structural diagram of a display device according to an embodiment of the present application.

### DETAILED DESCRIPTION OF EMBODIMENTS

The following description of each embodiment, with reference to the accompanying drawings, is used to exemplify specific embodiments which may be carried out in the present invention. Directional terms mentioned in the present invention, such as “top”, “bottom”, “front”, “back”, “left”, “right”, “inside”, “outside”, “side”, etc., are only used with reference to the orientation of the accompanying drawings. Therefore, the used directional terms are intended to illustrate, but not to limit, the present invention. In the drawings, components having similar structures are denoted by the same numerals.

In the description of the present invention, it is to be understood that the terms such as “center”, “longitudinal”, “transverse”, “length”, “width”, “thickness”, “upper”, “lower”, “front”, “rear”, “left”, “right”, “vertical”, “horizontal”, “top”, “bottom”, “inside”, “outside”, “clockwise”, “counterclockwise”, etc., the orientation or positional relationship of the indications is based on the orientation or positional relationship shown in the drawings, and is merely for the convenience of the description of the invention and the simplified description, rather than indicating or implying that the device or component referred to has a specific orientation, in a specific orientation. The construction and operation are therefore not to be construed as limiting the invention. In addition, unless otherwise defined, any technical or scientific term used herein shall have the common meaning understood by a person of ordinary skills. Such words as “first” and “second” used in the specification and claims are merely used to differentiate different components rather than to represent any order, number or importance. In the description of the present invention, the meaning of “plurality” is two or more unless specifically defined otherwise.

In the description of this application, it should be noted that the terms “installation”, “connected”, and “coupled” should be understood in a broad sense, unless explicitly stated and limited otherwise. For example, they may be fixed connections, removable connected or integrally connected; it can be mechanical, electrical, or can communicate with each other; it can be directly connected, or it can be indirectly connected through an intermediate medium, it can be an internal communication of two elements or an interaction relationship of two elements. For those of ordinary skill in the art, the specific meanings of the above terms in this application can be understood according to specific situations.

In the present invention, the first feature “on” or “under” the second feature can include direct contact of the first and second features, and can also be included that the first and second features are not in direct contact but are contacted by additional features between them, unless otherwise specifically defined and defined. Moreover, the first feature is “above”, “on”, and “on the top of” of the second feature, including the first feature directly above and diagonally above the second feature, or simply means that the first feature is horizontally higher than the second feature. The first feature is “under”, “below”, and “beneath” the second feature, including the first feature directly below and diagonally below the second feature, or merely the first feature is horizontally less than the second feature.

The following disclosure provides many different implementations or examples for implementing different structures of the present application. To simplify the disclosure of the present application, the components and settings of specific examples are described below. Of course, they are merely examples and are not intended to limit the application. Furthermore, the present application may repeat reference numbers and/or reference letters in different examples, and such repetition is for the sake of simplicity and clarity, and does not by itself indicate a relationship between the various embodiments and/or settings discussed. In addition, examples of various specific processes and materials are provided in this application, but those of ordinary skill in the art can be aware of the application of other processes and/or the use of other materials.

The technical solution of the present application will now be described in conjunction with specific embodiments.

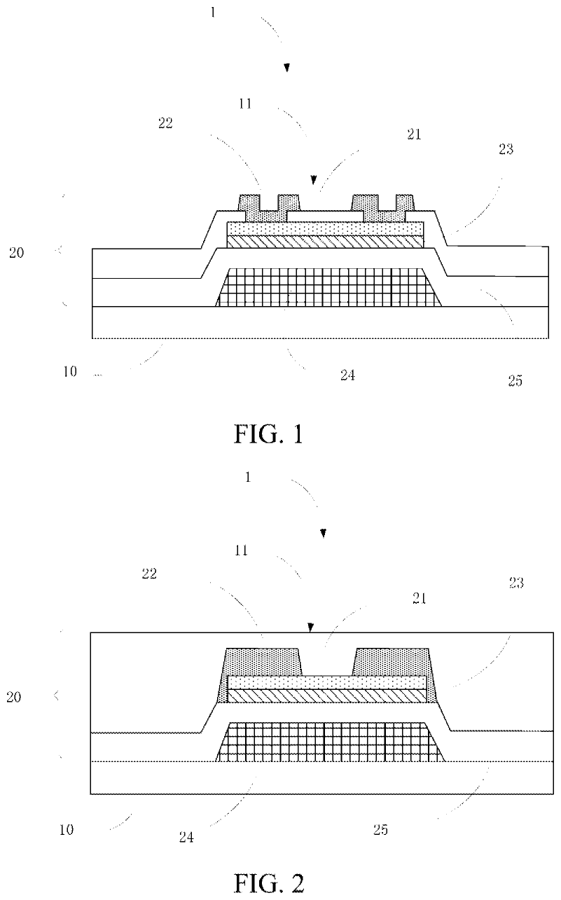

The present application provides a photoelectric conversion device 1, as shown in FIG. 1 to FIG. 3, including a substrate 10 and a thin film transistor unit layer 20 arranged on the substrate 10. The photoelectric conversion device 1 includes a photosensitive surface 11, and the thin film transistor unit layer 20 includes:

an active layer 21 configured to generate electron-hole pairs for photon absorption and carrier transmission;

a source-drain metal layer 22 positioned at both ends of the active layer 21 and electrically connected to the active layer 21; and

a photonic crystal functional layer 23 disposed on a side of the active layer 21 away from the photosensitive surface 11.

It is understandable that a conventional photoelectric conversion is limited by the narrow band gap of the active material, which can only respond to light of a specific wavelength band. A light response performance is weak and the light utilization rate is low, which makes a response performance of the photoelectric conversion device 1 lower. By applying a photonic crystal technique to the photoelectric conversion device 1, the photonic crystal functional layer 21 is disposed on the side of the active layer 21 away from the photosensitive surface 11, and the light incident from the photosensitive surface 11 is reflected by the photonic crystal functional layer 23 to the active layer 21 to realize a secondary stimulus response of the active layer 21 to light, enhancing the photoelectric conversion device 1 and improving the response performance. In addition, the photonic crystal functional layer 23 can also convert light in other bands that the active layer 21 cannot respond to into light that the active layer 21 can respond to, which further improves the light utilization efficiency of the photoelectric conversion device 1 and adaptability to light in different bands.

As mentioned above, in the present embodiment, the photosensitive surface 11 of the photoelectric conversion device 1 can be set according to actual application, which is not limited thereto. Specifically, when the photosensitive surface 11 is irradiated with incident light, the active layer 21 receives a first stimulus response, and then, the incident light is reflected to the active layer 21 through the photonic crystal functional layer 23, and the active layer 21 receives the secondary stimulus response to achieve an effect of improving the light utilization efficiency, enhancing the responsiveness of incident light of the photoelectric conversion device 1, and improving the precision and sensitivity of the photoelectric conversion device 1.

In an embodiment, the photonic crystal functional layer 23 is an inverse opal structure. It can be understood that the inverse opal structure of the photonic crystal functional layer 23 is a structure with a large specific surface area. Specifically, the photonic crystal uses new nanomaterials with adjustable light propagation. The band gap scattering and diffusing effects of the photonic crystal can be used to enhance the interaction between the light and the electrode, while greatly improving the light utilization rate. In addition, the photonic crystal functional layer 23 is an inverse opal structure with 100% refraction of the incident light, which can greatly enhance the light response performance of the photoelectric conversion device 1, and the photosensitivity of the photoelectric conversion device 1 is significantly improved. Specifically, the photon inverse opal structure in the photonic crystal functional layer 23 is generally prepared by a hard-templating method. First, the microspheres are regularly deposited into the opal structure to obtain a template, and then a precursor is poured into the opal structure, and the template is removed to obtain the inverse opal structure. Obviously, in this process, pore sizes in the inverse opal structure of the photonic crystal functional layer 23 can be adjusted according to a size of the template, thereby to realize a band gap adjustment of the photonic crystal functional layer 23, which is practical and convenient.

In an embodiment, a material of the photonic crystal functional layer 23 is same as a material of the active layer 21. Obviously, the material of the active layer 21 is a semiconductor material, when the material of the photonic crystal functional layer 23 is same as the material of the active layer 21, the photonic crystal functional layer 23 can reflect the light of the responsive wavelength band of the active layer 21 onto the active layer 21, increasing the intensity of the incident light, and enhancing an interaction efficiency between the active layer 21 and the incident light. Specifically, the material of the photonic crystal functional layer 23 and the material of the active layer 21 are both amorphous silicon.

In addition, the material of the photonic crystal functional layer 23 can also be narrow-band gap metal oxides such as zirconium oxide, silicon oxide, tungsten oxide, manganese oxide, titanium oxide, and germanium oxide. For example, when the material of the photonic crystal functional layer 23 is germanium metal oxide, such as germanium oxide, which is sensitive to light in the infrared band, the photonic crystal functional layer 23 will enhance absorption and reflection of part of the light in the infrared band of the incident light. In addition, when the material of the photonic crystal functional layer 23 is titanium metal oxide, such as titanium oxide, which is sensitive to ultraviolet light, the photonic crystal functional layer 23 also enhances absorption and reflection of part of the ultraviolet light in the incident light. Of course, when the material of the photonic crystal functional layer 23 uses other narrow band-gap metal oxides, the corresponding effects will be produced according to the specific sensitive wavelength band of the narrow band-gap metal oxides, which will not be repeated here.

In an embodiment, the photonic crystal functional layer 23 is doped with lanthanide metal oxides or rare earth elements. The photonic crystal functional layer 23 can be doped with lanthanide metal oxides such as ytterbium (Yb), erbium (Er), etc., or doped with rare earth elements, so that the photonic crystal functional layer 23 has the function of absorbing and converting light in a specific wavelength band of the incident light into a sensitive band of the active layer 21 to realize that the photoelectric conversion device 1 has the light responsiveness performance in more wavelength bands, improving the adaptability of the photoelectric conversion device 1.

It is worth noting that a center position of the band gap of the photonic crystal functional layer 23, that is, a wavelength band of light converted by the photonic crystal functional layer 23, can be adjusted by adjusting pore sizes in the inverse opal structure of a photonic crystal function to realize the band gap adjustment of the photonic crystal functional layer 23. The larger the pore sizes in the inverse opal structure, the band gap of the photonic crystal functional layer 23 will generate a phenomenon of redshift. Specifically, for example, when the material of the photonic crystal functional layer 23 is TiO2, after adjusting the pore sizes in the inverse opal structure of the photonic crystal function from 193 nanometer (nm) to 260 nm, a wavelength of the band gap of the photonic crystal function is adjusted from 420 nm to 680 nm.

It can be understood that the material of the active layer 21 includes any one of low temperature polysilicon (LTPS), amorphous silicon (a-Si), or indium gallium zinc oxide (IGZO). Specifically, the thin film transistor unit layer 20 may have a top gate structure, a bottom gate structure, or other structures, which is not limited thereto. The photonic crystal functional layer 23 having a light intensity gain for the incident light and/or a wavelength conversion for the incident light realizes enhancement of the photoelectric performance of the photoelectric conversion device 1.

In an embodiment, as shown in FIG. 1 to FIG. 2, the thin film transistor unit layer 20 has a bottom gate structure, and the thin film transistor unit layer 20 further includes:

a gate layer 24 provided on the substrate 10;

a gate insulating layer 25 disposed on the substrate 10 and the gate insulating layer 25, and covering the gate layer 24; wherein the active layer 21 is disposed on the gate insulating layer 25.

Obviously, as shown in FIG. 1 to FIG. 2, the photoelectric conversion device 1 includes a photosensitive surface 11, and the photosensitive surface 11 is disposed on a side of the photoelectric conversion device 1 away from the gate layer 24, which is a top side of the photoelectric conversion device 1. The photonic crystal functional layer 23 is disposed on the side of the active layer 21 away from the photosensitive surface 11. Of course, the photosensitive surface 11 can also be disposed on the side of the photoelectric conversion device 1 away from the gate layer 24. In addition, the gate layer 24 can also be made of a transparent electrode material such as indium tin oxide (ITO) to reduce a blocking rate of the gate layer 24 against incident light, which will not be repeated here.

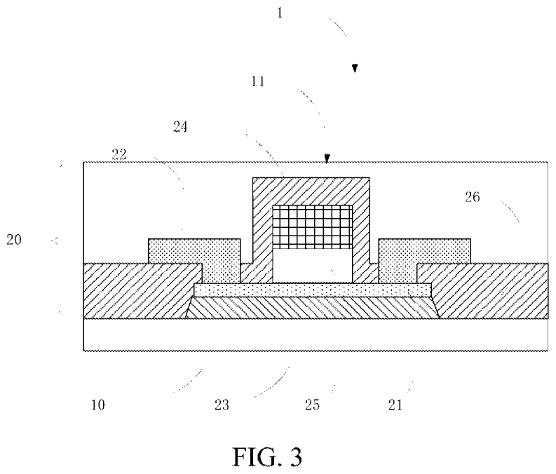

In an embodiment, as shown in FIG. 3, the thin film transistor unit layer 20 is a top gate structure, and the thin film transistor unit layer 20 further includes:

a gate insulating layer 25 disposed on the active layer 21;

a gate layer 24 disposed on the gate insulating layer 25; and

an interlayer insulating layer 26 disposed on the gate insulating layer 25 and completely covering the gate layer 24; wherein the source-drain metal layer 22 is electrically connected to both ends of the active layer 21 through the interlayer insulating layer 26.

Obviously, as shown in FIG. 3, the photoelectric conversion device 1 includes a photosensitive surface 11, and the photosensitive surface 11 is disposed on a side of the photoelectric conversion device 1 away from the gate layer 24, that is, a bottom side of the photoelectric conversion device 1. The photonic crystal functional layer 23 is disposed on the side of the active layer 21 away from the photosensitive surface 11. Of course, the photosensitive surface 11 can also be disposed on the side of the photoelectric conversion device 1 away from the gate layer 24. In addition, the gate layer 24 can also be made of a transparent electrode material such as indium tin oxide (ITO) to reduce a blocking rate of the gate layer 24 against incident light, which will not be repeated here.

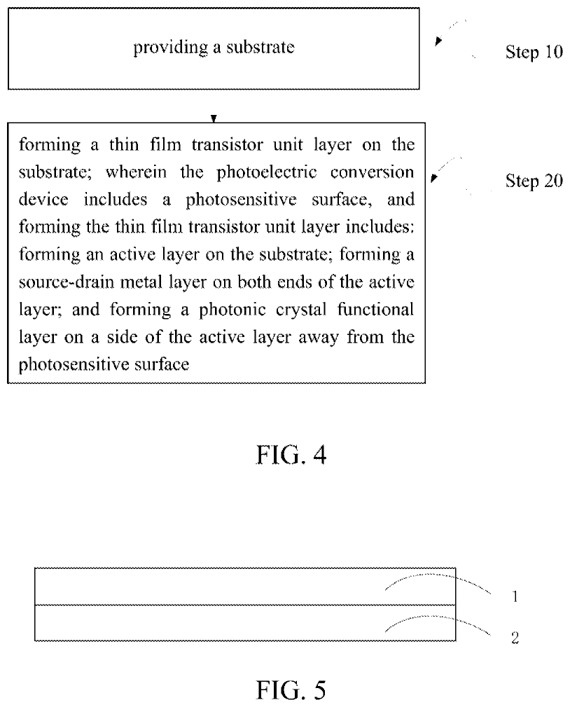

The present application further provides a method of manufacturing the photoelectric conversion device 1, as shown in FIG. 4, including following steps:

step S10, providing a substrate 10; and

step S20, forming a thin film transistor unit layer 20 on the substrate 10; wherein the photoelectric conversion device 1 includes a photosensitive surface 11, and forming the thin film transistor unit layer 20 includes:

forming an active layer 21 on the substrate 10;

forming a source-drain metal layer 22 on both ends of the active layer 21; and

forming a photonic crystal functional layer 23 on a side of the active layer 21 away from the photosensitive surface 11.

In an embodiment, the photonic crystal functional layer 23 is formed by one of chemical vapor deposition process, atomic layer deposition process, sol-gel process, or two-photon laser direct writing process. It can be understood that the photonic crystal functional layer 23 is the inverse opal structure. The inverse opal structure in the photonic crystal functional layer 23 is generally prepared by a hard-templating method. First, the microspheres are regularly deposited into the opal structure to obtain a template, and then a precursor is poured into the opal structure, and the template is removed to obtain the inverse opal structure. Obviously, in this process, pore sizes in the inverse opal structure of the photonic crystal functional layer 23 can be adjusted according to a size of the template, thereby to realize a band gap adjustment of the photonic crystal functional layer 23, which is practical and convenient.

The preparation of the photonic crystal functional layer 23 using the chemical vapor deposition process includes: depositing a gaseous precursor reactant on a substrate through the principle of vapor phase reaction-deposition, and obtaining a desired inverse phase structure by using a gas to enter a template. Specifically, a silicon inverse opal structure can be selected and silicon ethane gas is selected as a precursor to uniformly deposit silicon nanoclusters on an opal interface, followed by a heat treatment at an appropriate temperature to obtain an inverse silicon opal structure. Meanwhile, the opal structure can be selected from silica (SiO2), polystyrene (PS), or polymethyl methacrylate (PMMA), by gravity sedimentation or self-assembly method, evaporation method, dipping-pulling method, or photolithography method to form the photonic crystal functional layer 23.

The preparation of the photonic crystal functional layer 23 using the atomic layer deposition process includes: selecting different materials, such as TiO2, CeO2, etc. of the photonic crystal functional layer 23 according to a selection of different wavelengths. For example, selecting TiO2 and using SiO2 opal photonic crystals as a template, under the condition of 90° C. to 120° C., TiCl4 and H2O are alternately fed in a pulsed manner, during which appropriate amount of nitrogen is fed, and finally the template is removed by HF, calcined at high temperature to obtain a TiO2 photonic crystal functional layer 23 with a uniform structure.

The preparation of the photonic crystal functional layer 23 using the sol-gel process includes: using a compound containing a highly chemically active component as a precursor, after uniformly mixing and filling these raw materials in a liquid phase, performing hydrolysis and condensation to form a stable and transparent sol system, the sol further matures to form a gel with a three-dimensional network structure. After the gel is dried, sintered and solidified, and the template is removed, the photonic crystal functional layer 23 having an inverse opal structure can be obtained.

The preparation of the photonic crystal functional layer 23 using the two-photon laser direct writing technique includes: constructing by the two-photon laser direct writing process, that is, the two-photon laser direct writing is configured to construct a special photonic crystal structure for a film layer, materials are various choices, which can be adjusted according to an actual light wavelength that needs a gain.

The present application further provides a display device, as shown in FIG. 5, including the photoelectric conversion device 1 according to any one of the previous embodiments. It can be understood that the display device includes a display panel 2, the photoelectric conversion device 1 can be provided on the display panel 2 for receiving an external beam signal, and the display device performs a corresponding display control operation on the display panel 2 according to the sensed external beam signal. Therefore, the high responsiveness of the display device to the light control signal and the better adaptability of the band width are achieved, which will not be repeated here.

The present application provides a photoelectric conversion device 1, a method of manufacturing same, and a display device thereof. By applying a photonic crystal technique to the photoelectric conversion device 1, the photonic crystal functional layer 21 is disposed on the side of the active layer 21 away from the photosensitive surface 11, and the light incident from the photosensitive surface 11 is reflected by the photonic crystal functional layer 23 to the active layer 21, to realize a secondary stimulus response of the active layer 21 to light, enhancing the photoelectric conversion device 1 and improving the response performance. In addition, the photonic crystal functional layer 23 can also convert light in other bands that the active layer 21 cannot respond to into light that the active layer 21 can respond to, which further improves the light utilization efficiency of the photoelectric conversion device 1 and adaptability to light in different bands.

Embodiments of the present invention have been described, but not intended to impose any unduly constraint to the appended claims. For a person skilled in the art, any modification of equivalent structure or equivalent process made according to the disclosure and drawings of the present invention, or any application thereof, directly or indirectly, to other related fields of technique, is considered encompassed in the scope of protection defined by the claims of the present invention.

1. A photoelectric conversion device, comprising a substrate and a thin film transistor unit layer arranged on the substrate, the photoelectric conversion device comprising a photosensitive surface, wherein the thin film transistor unit layer comprises:
an active layer;
a source-drain metal layer positioned at both ends of the active layer and electrically connected to the active layer; and
a photonic crystal functional layer disposed on a side of the active layer away from the photosensitive surface.

2. The photoelectric conversion device of claim 1, wherein the photonic crystal functional layer comprises an inverse opal structure.

3. The photoelectric conversion device of claim 2, wherein a material of the photonic crystal functional layer is same as a material of the active layer.

4. The photoelectric conversion device of claim 2, wherein a material of the photonic crystal functional layer is one of zirconia, silicon oxide, tungsten oxide, manganese oxide, titanium oxide, germanium oxide, or polycrystalline silicon.

5. The photoelectric conversion device of claim 2, wherein the photonic crystal functional layer is doped with a lanthanide metal oxide or a rare earth element.

6. The photoelectric conversion device of claim 1, wherein the thin film transistor unit layer further comprises:
a gate layer provided on the substrate; and
a gate insulating layer disposed on the substrate and covering the gate layer, wherein the active layer is disposed on the gate insulating layer.

7. The photoelectric conversion device of claim 1, wherein the thin film transistor unit layer further comprises:
a gate insulating layer disposed on the active layer;
a gate layer disposed on the gate insulating layer; and
an interlayer insulating layer disposed on the gate insulating layer and completely covering the gate layer, wherein the source-drain metal layer is electrically connected to the both ends of the active layer through the interlayer insulating layer.

8. A method of manufacturing a photoelectric conversion device, comprising following steps:
providing a substrate; and
forming a thin film transistor unit layer on the substrate, wherein the photoelectric conversion device comprises a photosensitive surface, and forming the thin film transistor unit layer comprises:
forming an active layer on the substrate;
forming a source-drain metal layer on both ends of the active layer; and
forming a photonic crystal functional layer on a side of the active layer away from the photosensitive surface.

9. The method of manufacturing the photoelectric conversion device of claim 8, wherein the photonic crystal functional layer is formed by one of chemical vapor deposition process, atomic layer deposition process, sol-gel process, or two-photon laser direct writing process.

10. A display device comprising the photoelectric conversion device of claim 1.

11. The display device of claim 10, wherein the photonic crystal functional layer comprises an inverse opal structure.

12. The display device of claim 11, wherein a material of the photonic crystal functional layer is same as a material of the active layer.

13. The display device of claim 11, wherein a material of the photonic crystal functional layer is one of zirconia, silicon oxide, tungsten oxide, manganese oxide, titanium oxide, germanium oxide, or polycrystalline silicon.

14. The display device of claim 11, wherein the photonic crystal functional layer is doped with a lanthanide metal oxide or a rare earth element.

15. The display device of claim 10, wherein the thin film transistor unit layer further comprises:
a gate layer provided on the substrate; and
a gate insulating layer disposed on the substrate and covering the gate layer; wherein the active layer is disposed on the gate insulating layer.

16. The display device of claim 10, wherein the thin film transistor unit layer further comprises:
a gate insulating layer disposed on the active layer;
a gate layer disposed on the gate insulating layer; and
an interlayer insulating layer disposed on the gate insulating layer and completely covering the gate layer, wherein the source-drain metal layer is electrically connected to the both ends of the active layer through the interlayer insulating layer.
